(19) United States
(12) Patent Application Publication
(10) Pub. No.: US 2024/0337442 A1
(43) Pub. Date: Oct. 10, 2024

(54) METHOD AND DRYING DEVICE

(71) Applicant: Carl Zeiss SMT GmbH, Oberkochen (DE)

(72) Inventor: Arvid Maczeyzik, Aalen (DE)

(21) Appl. No.: 18/746,596

(22) Filed: Jun. 18, 2024

Related U.S. Application Data
(63) Continuation of application No. PCT/EP2022/085607, filed on Dec. 13, 2022.

(30) Foreign Application Priority Data
Dec. 23, 2021 (DE) 10 2021 214 981.2

(51) Int. Cl. F26B 21/00; F26B 21/08; F26B 21/14; G03F 7/00

(52) U.S. Cl. CPC F26B 21/001; F26B 21/083; F26B 21/14; G03F 7/7085; G03F 7/70925; G03F 7/70933

(57) ABSTRACT

A method for drying a cavity provided in a component of a projection exposure apparatus comprises: a) charging the cavity with a gas, wherein a liquid taken up in the cavity at least partially evaporates, and the gas together with the evaporated liquid is transported away out of the cavity as process exhaust air; b) detecting the relative humidity of the process exhaust air, wherein in step a) at least one change of direction of the gas, in which a direction of flow of the gas through the cavity is reversed, and/or at least one pressure surge is performed in dependence on the relative humidity of the process exhaust air; and c) applying a negative pressure to the cavity as soon as the relative humidity of the process exhaust air falls below a specified humidity value during step b).

### CROSS-REFERENCE TO RELATED APPLICATIONS

The present application is a continuation of, and claims benefit under 35 USC 120 to, international application No. PCT/EP2022/085607, filed Dec. 13, 2022, which claims benefit under 35 USC 119 of German Application No. 10 2021 214 981.2, filed Dec. 23, 2021. The entire disclosure of each of these applications is incorporated by reference herein.

### FIELD

The present disclosure relates to a method for drying a cavity provided in a component of a projection exposure apparatus and to a drying device for drying a cavity provided in a component of a projection exposure apparatus.

Microlithography is used for producing microstructured components, such as, for example, integrated circuits. The microlithography process is performed using a lithography apparatus, which has an illumination system and a projection system. The image of a mask (reticle) illuminated via the illumination system is in this case projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range from 0.1 nm to 30 nm, such as 13.5 nm, are currently under development. In the case of such EUV lithography apparatuses, because of the relatively high absorption of light of this wavelength by most materials, reflective optical units, that is to say mirrors, are typically used instead of—as previously—refractive optical units, that is to say lens elements.

The temperature of components of such lithography apparatuses, such as for example a collector of an EUV light source, the illumination system or the projection system, are to be controlled during operation. Provided for this are cooling channels that are led through the respective component. These cooling channels may be formed as complexly as desired and branched in any way desired. A cooling liquid, for example water, is passed through the cooling channels. An escape of the cooling liquid due to leaks should be avoided during the operation of the respective component.

The component or the cooling channel or the cooling channels is often subjected to a leak test before the component is put into operation or after the component is exchanged. Using such a leak test, it is possible to identify leaks that are present in a wall of the cooling channel. As previously mentioned, the identification of such leaks is relevant to avoiding an undesired escape of the cooling liquid from the cooling channel during the operation of the component.

A leak test, as mentioned previously, may be performed via helium, which can even pass through tiny leaks. For the leak test, a vacuum can be applied outside the cooling channel and the cooling channel can be flooded with helium. If possibly present leaks are then filled with drops of the cooling liquid, the cooling liquid freezes when the vacuum is applied, and thereby seals the leaks. The helium only diffuses very slowly through these frozen drops of the cooling liquid, and so the leak cannot be detected. Therefore, good drying of the cooling channel is desirable for a meaningful result of the leak test.

### SUMMARY

The present disclosure seeks to provide an improved method for drying a cavity provided in a component.

According to an aspect, the disclosure provides a method for drying a cavity provided in a component of a projection exposure apparatus is proposed. The method comprises the steps of: a) charging the cavity with a gas, wherein a liquid taken up in the cavity at least partially evaporates, and wherein the gas together with the evaporated liquid is transported away out of the cavity as process exhaust air, b) detecting the relative humidity of the process exhaust air, wherein in step a) at least one change of direction of the gas, in which a direction of flow of the gas through the cavity is reversed, and/or at least one pressure surge is performed in dependence on the relative humidity of the process exhaust air, and c) applying a negative pressure to the cavity as soon as the relative humidity of the process exhaust air falls below a specified humidity value during step b), wherein the liquid remaining in the cavity freezes and sublimates, and wherein the sublimated liquid is transported away out of the cavity as sublimate.

The fact that at least one change of direction of the gas and/or a pressure surge is performed in step a) means that the time for drying the cavity can be reduced significantly in comparison with a method without such a change of direction of the gas and/or without such a pressure surge.

The method can be performed before the component is put into operation or after the component is exchanged. The component may be any desired component of the projection exposure apparatus. For example, the component can be a collector of an EUV light source, an illumination optical unit or a projection optical unit of the projection exposure apparatus. The component can be an illumination optical unit, as previously mentioned, or part of an illumination optical unit of the projection exposure apparatus. The component can weigh, for example, more than 6.5 tons. The component may be at least partially produced from a metallic material. The projection exposure apparatus may be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light of between 30 nm and 250 nm.

The cavity can be a cooling channel led through the component. That is to say that the terms “cavity” and “cooling channel” can be interchanged as desired. In general, the component may have any desired number of cavities, which may be formed as complexly as desired and branched and converged again in any way desired. The liquid, in the present case a cooling liquid, such as water, is passed through the cavity in order to control the temperature of the component, that is to say to cool or heat it. The liquid is accordingly a cooling liquid. That is to say in particular that the terms “liquid” and “cooling liquid” can be interchanged as desired.

The gas can be a dry industrial gas, for example nitrogen, pre-dried and cleaned indoor air or artificially generated and cleaned compressed air CDA or xCDA (short for: Clean Dry Air, CDA/extreme Clean Dry Air, xCDA). When charging the cavity with the gas, the gas is passed through the cavity, and so the gas flushes the cavity. In the cavity there are at least drops of the liquid, which at least partially evaporate and are discharged together with the gas out of the cavity as process exhaust air. The gas may be heated before charging the cavity. However, the gas can be at room temperature or a temperature lying slightly above room temperature. As a result, undesired heating of the component is prevented.

For detecting the relative humidity of the process exhaust air, such as a moisture sensor or an air-mass flow meter is provided. For performing the change of direction of the gas in step a), the relative humidity of the process exhaust air can be used as a criterion of whether and when a change of direction of the gas is performed. For example, the change of direction of the gas may be performed whenever a value of the relative humidity of the process exhaust air no longer varies, in other words stagnates. Alternatively, the change of direction of the gas may also be performed whenever the relative humidity reaches or does not go any further below a specified value.

The “relative humidity” should be understood in the present case as meaning the percentage ratio between the momentary vapour pressure of the liquid, for example water, and the saturation vapour pressure of the liquid over a clean and flat surface of the liquid. A “change of direction of the gas” should be understood in the present case as meaning in particular a turning around or reversal of the direction of flow of the gas through the cavity.

A “pressure surge” is preferably characterized in that a pressure of the gas in the cavity briefly rises and then falls again. This can be achieved for example by rapid closing and opening of valves. The pressure surge may be performed instead of the change of direction of the gas. The pressure surge may alternatively also be performed with or during the change of direction of the gas. That is to say that both the change of direction of the gas and the pressure surge may be performed. With each change of direction of the gas, a pressure surge may be performed. However, changes of direction of the gas may also be performed without a pressure surge. A pressure surge may last a few milliseconds.

For applying the negative pressure to the cavity, a vacuum pump can be provided. If the relative humidity of the process exhaust air falls in step b) below a specified humidity value, for example five percent of relative humidity, step c) is performed. Applying the negative pressure or vacuum has the effect that the residual liquid remaining in the cavity freezes and sublimates. “Sublimates” should be understood in the present case as meaning the phase transition from solid to gaseous. That is to say that the liquid freezes into ice and the ice evaporates directly, without first melting. The terms “vacuum” and “negative pressure” can in the present case be interchanged as desired.

According to one embodiment, the at least one change of direction of the gas and/or the at least one pressure surge is performed whenever the relative humidity in the process exhaust air stagnates or reaches a specified value, for example five to thirty percent.

In order to detect whether the relative humidity in the process exhaust air stagnates, for example the relative humidity of the gas supplied may be compared with the relative humidity of the process exhaust air discharged. The relative humidity of the gas can be known. Consequently, a difference in the humidity between the gas and the process exhaust air can be determined. For example the change of direction of the gas is performed whenever the relative humidity does not fall any further below the specified value. If the relative humidity does not fall any further below the specified value, it means that the gas is no longer taking up any further humidity. In this case, it can be desirable to perform a change of direction of the gas.

According to an embodiment, two to three changes of direction of the gas are performed.

At least, one change of direction of the gas is performed. It is also possible however for more than three changes of direction of the gas to be performed. There can be any desired number of changes of direction of the gas.

According to an embodiment, with the at least one change of direction of the gas, a number of pressure surges are performed with the gas.

There can be any desired number of pressure surges. The pressure surges cause drops of liquid that are present in the cavity to burst into smaller drops. An increase in the size of the surface area is achieved as a result, whereby the liquid evaporates more easily and can be discharged together with the gas as process exhaust air. The pressure surges can also significantly reduce the time for drying the cavity. The pressure surges may also be performed as an alternative to the change of direction of the gas. The pressure surges may however also be performed with the change of direction of the gas.

According to an embodiment, approximately five to ten pressure surges are performed, each with a duration of a few milliseconds.

In general, there can be any desired number of pressure surges. It is also possible for different numbers of pressure surges to be performed with each change of direction of the gas. The pressure surges may also last longer than a few milliseconds. A time period or pause of half a second to ten seconds may be provided between the individual pressure surges.

According to an embodiment, in step b) a difference in the humidity of the gas and the process exhaust air is determined.

The relative humidity of the gas can be known. For example, the gas may be supplied via a gas supply in the form of a pump, a gas bottle, a gas line or a compressor. A drying unit may be provided upstream of the gas supply.

According to an embodiment, the method also comprises a step d) of detecting the negative pressure in the cavity, wherein steps a), b) and c) are performed until in step c) a specified negative-pressure threshold value of the negative pressure is reached within a specified time period.

The negative-pressure threshold value can lie below the so-called vapour-pressure limit of the liquid, such as of water. If the specified negative-pressure threshold value of the negative pressure can be reached within the specified time period, it can be assumed that the component or the cavity is dry. If the specified negative-pressure threshold value of the negative pressure cannot be reached within the specified time period, it can be assumed that there is still residual moisture in the cavity. In this case, steps a) to c) are performed again.

According to an embodiment, the specified negative-pressure threshold value lies below twenty three millibars, such as between one millibar and twenty millibars.

This can help ensure that the entire liquid present in the cavity freezes and sublimates. If the limit of twenty three millibars (water-vapour pressure at room temperature) is quickly reached, this is an indication that the drying was successful. If, on the other hand, the pressure stagnates just above twenty three millibars, this is an indication of continuing sublimation.

According to an embodiment, the specified time period is less than five minutes.

Some other suitable specified time period may also be chosen. For example, the specified time period is one to five minutes, for example three minutes.

According to an embodiment, the specified humidity value is less than five percent.

That is to say that the process exhaust air has a relative humidity of less than five percent. If this specified humidity value is reached, step c) is performed.

A drying device for drying a cavity provided in a component of a projection exposure apparatus is also proposed. The drying device can comprise a gas supply for supplying the drying device with a gas, a valve device for charging the cavity with the gas, wherein a liquid taken up in the cavity at least partially evaporates when the cavity is charged with the gas, and for transporting the gas together with the evaporated liquid away out of the cavity as process exhaust air, a moisture sensor for detecting the relative humidity of the process exhaust air, wherein at least one change of direction of the gas, involving a reversal of a direction of flow of the gas through the cavity, can be performed via the valve device in dependence on the relative humidity of the process exhaust air, and a vacuum pump for applying a negative pressure to the cavity as soon as the relative humidity of the process exhaust air falls below a specified humidity value, wherein the liquid remaining in the cavity freezes and sublimates, and wherein the sublimated liquid can be transported away out of the cavity as sublimate via the valve device.

The drying device is suitable, for example, for performing the aforementioned method. The gas supply may be a pump, a gas bottle, a compressor or a positive-pressure line, by way of which the gas, such as a dry industrial gas, for example nitrogen, or pre-dried and cleaned indoor air (CDA), can be supplied to the valve device. The valve device can comprise a multiplicity of valves which can be suitably switched for charging the cavity with the gas.

The moisture sensor can be arranged downstream of the valve device. “Downstream” means in the present case placed after the valve device along a direction of flow of the process exhaust air. A further valve may be provided upstream of the moisture sensor. The vacuum pump may also be assigned a valve. Using the latter valves, on the one hand the process exhaust air can be emitted to an area surrounding the drying device and on the other hand the vacuum pump can be fluidically connected to the cavity in order to apply the negative pressure to the cavity.

According to an embodiment, the valve device is designed to fluidically connect the gas supply optionally either to a first connection of the cavity or to a second connection of the cavity different from the first connection.

“Fluidically” means in the present case that the valve device is designed to establish a fluid connection between the gas supply and the cavity in such a way that the gas can flow from the gas supply into the cavity. Fluidically connecting the gas supply optionally to the first connection of the cavity or to the second connection of the cavity allows the change of direction of the gas to be implemented.

According to an embodiment, the valve device is designed to fluidically connect the vacuum pump optionally either to the first connection of the cavity or to the second connection of the cavity.

This can be achieved by suitable switching of the aforementioned valves of the valve device.

According to an embodiment, the valve device has valves assigned to the first connection of the cavity and valves assigned to the second connection of the cavity.

The valves can be formed as open/close valves. For example, the valves are solenoid valves.

According to an embodiment, the drying device also comprises a pressure sensor, arranged upstream of the vacuum pump, for detecting the negative pressure in the cavity.

That the pressure sensor is “arranged upstream” of the vacuum pump means in the present case in particular that the pressure sensor is arranged upstream of the vacuum pump along the direction of flow of the process exhaust air pumped away out of the cavity.

“A” or “an” in the present case should not necessarily be understood to be restrictive to exactly one element. Rather, a plurality of elements, such as for example two, three or more, may also be provided. Any other numeral used here should also not be understood to the effect that there is a restriction to exactly the stated number of elements. Rather, unless indicated otherwise, numerical deviations upwards and downwards are possible.

The embodiments and features described for the method apply correspondingly to the proposed drying device, and vice versa.

Further possible implementations of the disclosure also comprise not explicitly mentioned combinations of features or embodiments that are described above or below with respect to the exemplary embodiments. In this case, a person skilled in the art will also add individual aspects as improvements or supplementations to the respective basic form of the disclosure.

Further refinements and aspects of the disclosure are the subject of the dependent claims and also of the exemplary embodiments of the disclosure that are described below. The disclosure is explained in greater detail below on the basis of preferred embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of an embodiment of a drying device for drying a component of the projection exposure apparatus according to FIG. 1;

FIG. 3 shows a schematic partial sectional view of an embodiment of a component for the projection exposure apparatus according to FIG. 1;

FIG. 4 shows a further schematic partial sectional view of the component according to FIG. 3;

FIG. 5 shows a further schematic partial sectional view of the component according to FIG. 3;

FIG. 6 shows a further schematic partial sectional view of the component according to FIG. 3;

FIG. 7 shows a further schematic partial sectional view of the component according to FIG. 3;

FIG. 8 shows a further schematic partial sectional view of the component according to FIG. 3; and

FIG. 9 shows a schematic block diagram of an embodiment of a method for drying the component according to FIG. 3.

### DETAILED DESCRIPTION

Unless indicated otherwise, elements that are identical or functionally identical have been given the same reference signs in the figures. It should also be noted that the illustrations in the figures are not necessarily true to scale.

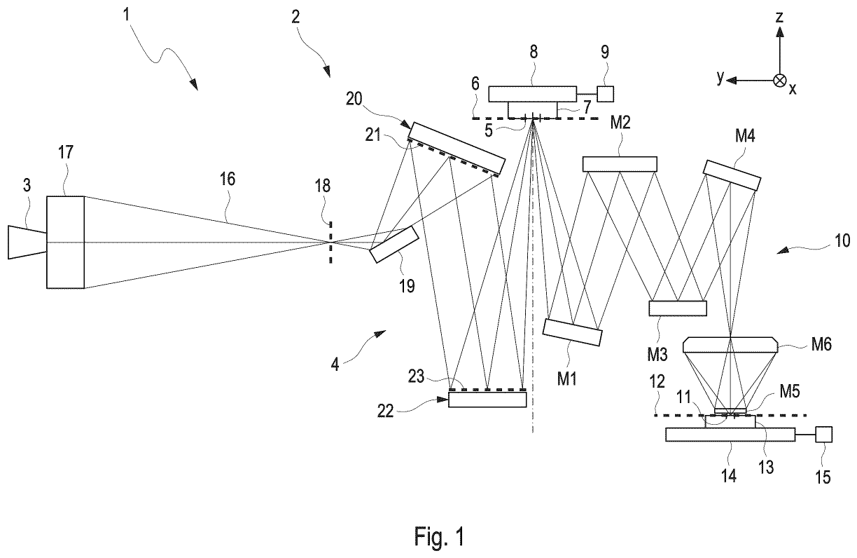

FIG. 1 shows an embodiment of a projection exposure apparatus 1 (lithography apparatus), in particular an EUV lithography apparatus. An embodiment of an illumination system 2 of the projection exposure apparatus 1 has in addition to a light or radiation source 3 an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs along the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15 in particular along the y-direction y. The displacement on the one hand of the reticle 7 by way of the reticle displacement drive 9 and on the other hand of the wafer 13 by way of the wafer displacement drive 15 may take place in such a way as to be synchronized with one another.

The light source 3 is an EUV radiation source. The light source 3 emits EUV radiation 16, which is also referred to below as used radiation, illumination radiation or illumination light. The used radiation 16 can have a wavelength in the range between 5 nm and 30 nm. The light source 3 may be a plasma source, for example an LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emerging from the light source 3 is focused by a collector 17. The collector 17 may be a collector with one or more ellipsoidal and/or hyperboloidal reflection surfaces. The at least one reflection surface of the collector 17 may be impinged upon by the illumination radiation 16 with grazing incidence (abbreviated as: GI), that is to say with angles of incidence greater than 45°, or with normal incidence (abbreviated as: NI), that is to say with angles of incidence less than 45°. The collector 17 may be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream of it in the beam path, a first facet mirror 20. The deflection mirror 19 may be a plane deflection mirror or, alternatively, a mirror with a beam-influencing effect that goes beyond the purely deflecting effect. Alternatively or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, such as as rectangular facets or as facets with an arcuate edge contour or an edge contour of part of a circle. The first facets 21 may be embodied as plane facets or alternatively as facets with convex or concave curvature.

As known for example from DE 10 2008 009 600 A1, the first facets 21 themselves may also be composed in each case of a multiplicity of individual mirrors, for example a multiplicity of micromirrors. The first facet mirror 20 may be formed as a microelectromechanical system (MEMS system). For details, reference is made to DE 10 2008 009 600 A1.

Between the collector 17 and the deflection mirror 19, the illumination radiation 16 travels horizontally, that is to say along the y-direction y.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 may have plane reflection surfaces or alternatively reflection surfaces with convex or concave curvature.

The illumination optical unit 4 consequently forms a doubly faceted system. This fundamental principle is also referred to as a fly's eye condenser (or fly's eye integrator).

It may be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

In a further embodiment, not shown, of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit may comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are similarly possible. The projection optical unit 10 is a twice-obscured optical unit. The penultimate mirror M5 and the last mirror M6 each have a through opening for the illumination radiation 16. The projection optical unit 10 has an image-side numerical aperture that is greater than 0.5 and may also be greater than 0.6, and may be for example 0.7 or 0.75.

Reflection surfaces of the mirrors Mi may be embodied as free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, such as with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may have an anamorphic form. It can have different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, that is to say in a direction perpendicular to the scanning direction.

The projection optical unit 10 leads to a reduction in size of 8:1 in the y-direction y, that is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 can be as homogeneous as possible. It can have a uniformity error of less than 2%. The field uniformity may be achieved by way of the overlay of different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, such as the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner may be achieved by a redistribution of the illumination channels.

Further aspects and details of the illumination of the object field 5, such as of the entrance pupil of the projection optical unit 10 are described below.

The projection optical unit 10 may have a homocentric entrance pupil. The latter may be accessible. It may also be inaccessible.

The entrance pupil of the projection optical unit 10 frequently cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the distance of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, such as an optical component part of the transfer optical unit, should be provided between the second facet mirror 22 and the reticle 7. With the aid of this optical element, the different poses of the tangential entrance pupil and the sagittal entrance pupil may be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted in relation to an arrangement plane defined by the deflection mirror 19. The first facet mirror 20 is arranged so as to be tilted with respect to an arrangement plane defined by the second facet mirror 22.

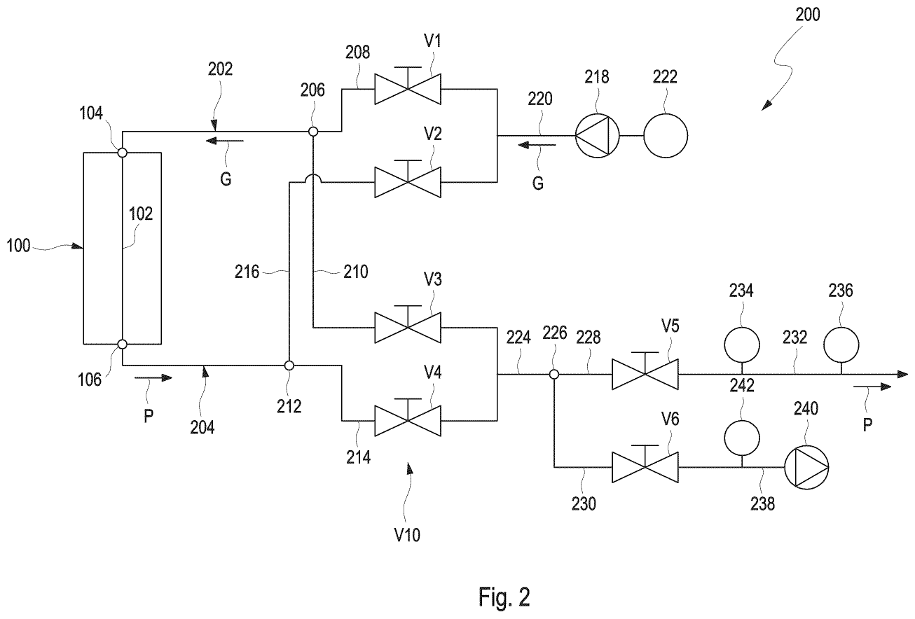

FIG. 2 shows a schematic view of a component 100. The component 100 may be an illumination optical unit 4 as mentioned above or be a part of such an illumination optical unit 4. The component 100 is at least partially produced from a metallic material. The component 100 comprises a multiplicity of cavities 102, only one of which however is shown in FIG. 2. The cavity 102 is a cooling channel and may therefore also be referred to as such.

The cavity 102 may be branched in any way desired or formed in any way desired. The cavity 102 has two connections 104, 106, for example a first connection 104 and a second connection 106, by which a cooling system (not shown) can be connected to the component 100. A cooling liquid, for example water, can be passed through the cavity 102.

Before the component 100 is put into operation or after it is exchanged, a leak test should be performed. For this purpose it is desirable to dry the component 100, for example the cavity 102.

A drying device 200 is used for drying the component 100. The drying device 200 comprises a first line 202, which can be connected to the first connection 104, and a second line 204, which can be connected to the second connection 106. The lines 202, 204 may be hoses, pipelines or the like.

The first line 202 branches at a branch 206 into a first line portion 208 and a second line portion 210. Accordingly, the second line 204 branches at a branch 212 into a first line portion 214 and a second line portion 216. The lines 202, 204 are consequently constructed substantially identically.

The first line portion 208 of the first line 202 leads to a first valve V1. The second line portion 216 of the second line 204 leads to a second valve V2. A gas supply 218 is connected to the valve V1, V2 via a line 220 branching to the two valves V1, V2. The gas supply 218 may be a pump, a compressor or a positive-pressure line, by way of which a gas G, such as a dry industrial gas, for example nitrogen, pre-dried and cleaned indoor air or artificially generated and cleaned compressed air CDA or xCDA (short for Clean Dry Air, CDA/extreme Clean Dry Air, xCDA), can be supplied to the valves V1, V2. Depending on which valve V1, V2 is open and closed, the gas G may then be supplied either to the first connection 104 or to the second connection 106.

A drying unit 222 may be arranged upstream of the gas supply 218. The drying unit 222 may be a drying cartridge, by which moisture can be extracted from the gas G. The drying unit 222 may comprise two columns which are filled with a silica gel. Using the drying unit 222, the gas G can be pre-dried. The objective here is a relative humidity of the gas G of 2 to 10%. An additional compressor, either oil-free or with an oil separator, may be used in order to achieve a pressure of the gas G of up to 8 bar.

The use of dried ambient air is more favourable than the use of an industrial gas. The drying unit 222 delivers the gas G with a defined relative humidity. In this way, the process of drying the component 100 is possible with known input parameters. When using a drying cartridge as the drying unit 222, the use of a silicate means that the drying unit 222 can be used unrestrictedly in terms of its location. Indoor air or ambient air can consequently be used as the gas G. The drying unit 222 may comprise a heating device. In this way, the drying unit 222 can be regenerated as desired and consequently can also be reused.

The second line portion 210 of the first line 202 leads to a third valve V3. The first line portion 214 of the second line 204 leads to a fourth valve V4. There can in principle be any desired number of valves V1 to V4. However, four valves V1 to V4 are always provided for each cavity 102. Accordingly, when there are for example twenty cavities 102, eighty valves V1 to V4 are also provided. In the present case, the valves V1, V3 are assigned to the first connection 104 and the valves V2, V4 are assigned to the second connection 106. The valves V1 to V4 together form a valve device V10.

From the valves V3, V4, a converging line 224 leads to a branch 226. From the branch 226, a line 228 leads to a fifth valve V5 and a line 230 leads to a sixth valve V6. The valves V5, V6 are connected in parallel.

From the fifth valve V5, a line 232 leads away. By way of the line 232, for example the moisture-laden gas G can be discharged as process exhaust air P. The line 232 has a temperature sensor 234 and a moisture sensor 236 for determining the moisture content of the process exhaust air P. The process exhaust air P may for example be discharged to an area surrounding the drying device 200. From the sixth valve V6, a line 238 leads to a vacuum pump 240. The line 238 is assigned a pressure sensor 242 for pressure measurement.

The function of the drying device 200 and a method for drying the component 100 are explained below on the basis of FIG. 2 and FIGS. 3 to 8, which each show a partial sectional view of the component 100 through a cavity 102 as explained above.

As mentioned above, the cavity 102 is subjected to a leak test before the component 100 is put into operation or after the component 100 is exchanged. Using such a leak test, it is possible to identify leaks 110 that are present in a wall 108 of the cavity 102. The identification of such leaks 110 is desirable with regard to the avoidance of an undesired escape of the cooling liquid K from the cavity 102 during the operation of the component 100. The liquid K is a cooling liquid, for example water. The terms “liquid” and “cooling liquid” can therefore be interchanged as desired.

The leak test is performed via helium, which can even pass through tiny leaks 110. So if these leaks are filled with drops of the liquid K, the liquid K freezes when a negative pressure is applied for performing the test, and thereby seals the leaks 110. The helium only diffuses very slowly through these frozen drops of the cooling liquid K, and so the leak 110 cannot be detected.

First, the liquid K, which can be water, is let out. Any appreciable amounts of the liquid K that are still remaining are blown out. The cavity 102 may be flooded with nitrogen to displace oxygen. This allows the risk of corrosion to be reduced.

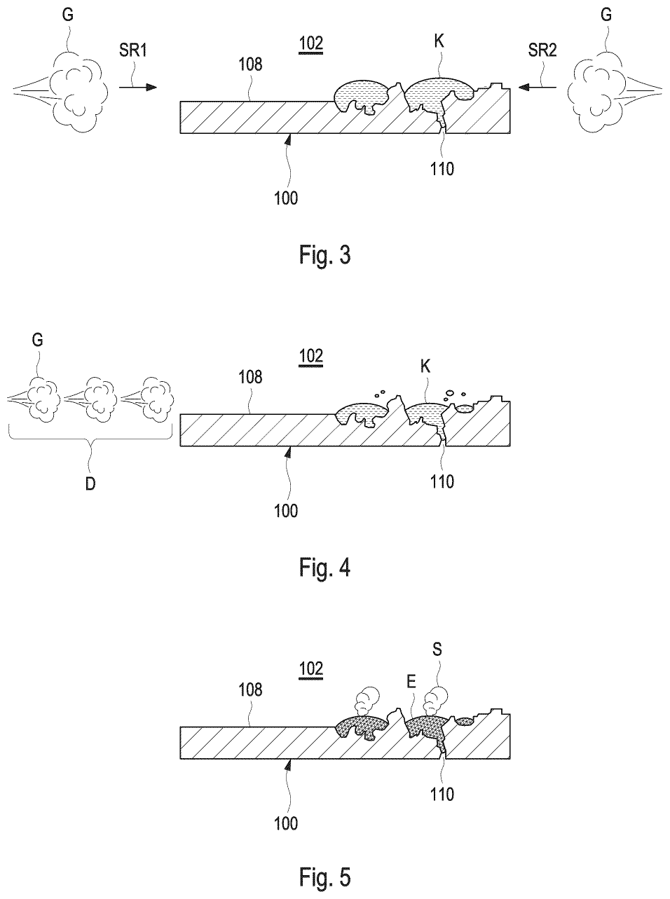

The drying device 200 is then connected to the connections 104, 106 of the component 100. All of the valves V1 to V6 are closed. Opening the valves V1, V4, V5 allows the cavity 102 to be flushed with the dry gas G. A change of direction of the gas G can be achieved here, as shown in FIG. 3, by alternately switching the valves V1, V4 and the valves V2, V3. That is to say that either the valves V1, V4 are open and the valves V2, V3 are closed or the valves V1, V4 are closed and the valves V2, V3 are open.

During the alternating opening and closing of the valves V1, V4 and the valves V2, V3, the fifth valve V5 constantly remains open, and so the moisture-laden gas G can be discharged as process exhaust air P. Using the temperature sensor 234, the temperature of the process exhaust air P can be determined. Using the moisture sensor 236, a moisture difference between the first connection 104 and the second connection 106 can be determined whenever the relative humidity of the gas G at the first connection 104 is known.

A stagnation of the relative humidity of the process exhaust air P or a pre-defined value of the relative humidity, of for example 5 to 30%, may be used as a criterion for a change of direction of the gas. At least one change of direction of the gas takes place. Optionally, two to three changes of direction of the gas may be performed. A “change of direction of the gas” should be understood in the present case as meaning a turning around or reversal of the direction of flow SR1, SR2 of the gas G through the cavity 102. In the orientation of FIG. 3, a first direction of flow SR1 is oriented from left to right and a second direction of flow SR2 is oriented from right to left.

With each change of direction of the gas, a number of pressure surges D may be performed with the gas G, as shown in FIG. 4. This may take place for example by the valves V1, V4 being briefly opened and then closed again a number of times one after the other. Using the pressure surges D, the drops of the liquid K that are located in the cavity 102 burst into smaller drops. This leads to an increase in the size of the surface area of the liquid K. The gas G can then take up the liquid K better. For example, 5 to 10 pressure surges D may be performed. A pressure surge D may last a few milliseconds. A time interval between two pressures surges D may be for example between 0.5 and 10 seconds. The relative humidity is also monitored via the moisture sensor 236.

The flushing of the cavity 102 with the gas G, the performing of the change of direction of the gas and/or the performing of the pressure surges D is continued until the residual moisture in the process exhaust air P tends towards zero. For example, a relative humidity of less than 5% may be used as a criterion.

As soon as the relative humidity falls below the aforementioned value, given by way of example, of 5%, a negative pressure is applied to the cavity 102. For this purpose, the valves V1, V2, V3, V5 are closed and the valves V4, V6 are opened. The vacuum pump 240 is put into operation. The aim here is to achieve within a specified time period of approximately 1 to 5 minutes a negative pressure below the vapour pressure limit of 23 mbar of the liquid K, in the present case water. A desirable target range lies between 1 and 20 mbar. The negative pressure in the cavity 102 is monitored via the pressure sensor 242.

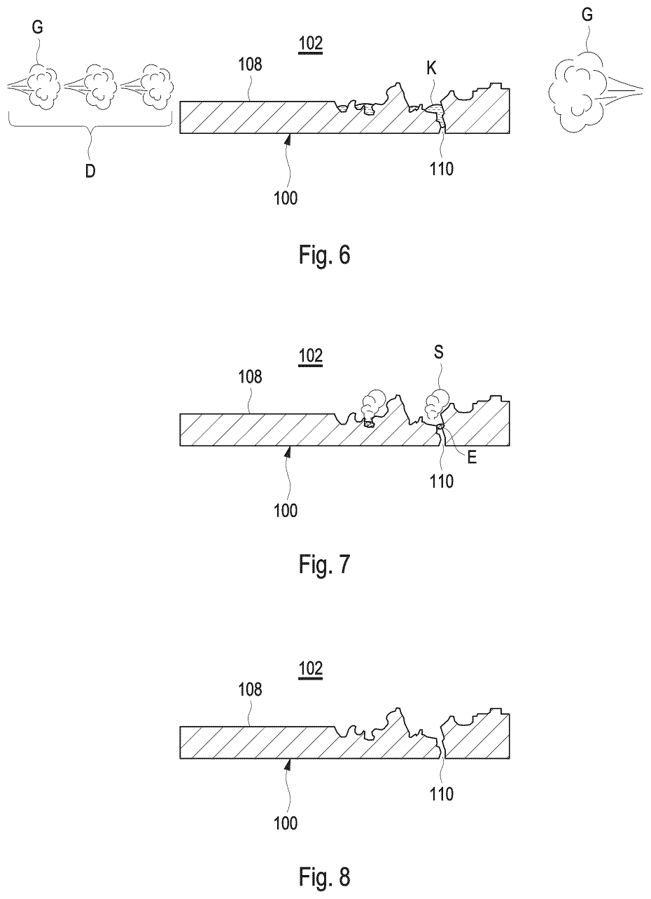

As shown in FIG. 5, the remaining liquid K freezes as ice E and goes over from the solid state of aggregation directly into the gaseous state of aggregation as sublimate S. The sublimate S is pumped away. If the aforementioned desired negative pressure value is not reached within the specified time period, the cavity 102 is flushed again with the gas G, as shown in FIG. 6. Changes of direction of the gas and/or pressure surges D may also be performed. The frozen liquid K thereby melts and evaporates.

Subsequently, as shown in FIG. 7, a negative pressure is again applied to the cavity 102. Residual liquid K remaining in the cavity 102 freezes as ice E and evaporates as sublimate S. The sublimate S is pumped away. If the aforementioned target value of the negative pressure is reached in the specified time period, it can be assumed that the cavity 102 is completely dry, as is shown in FIG. 8.

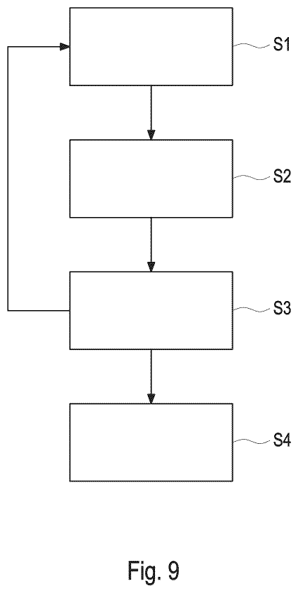

FIG. 9 shows a schematic block diagram of an embodiment of a method for drying the component 100 or the cavity 102, as already explained above.

In the method, in a step S1 the cavity 102 is charged with the gas G. The liquid K taken up in the cavity 102 is thereby at least partially evaporated. The gas G together with the evaporated liquid K is transported away out of the cavity 102 as process exhaust air P.

In a step S2, the relative humidity of the process exhaust air P is detected, wherein in step S1 at least one change of direction of the gas, in which the direction of flow SR1, SR2 of the gas G through the cavity 102 is reversed, is performed in dependence on the relative humidity of the process exhaust air P. In addition or as an alternative, at least one pressure surge D, as mentioned above, may also be performed. The pressure surge D may be performed with or during the change of direction of the gas. In step S2, a difference in the humidity between the gas G and the process exhaust air P is determined. Optionally, the relative humidity of the gas G is known.

A step S3 comprises applying a negative pressure to the cavity 102 as soon as the relative humidity of the process exhaust air P falls below a specified humidity value during step S2. The liquid K remaining in the cavity 102 thereby freezes and sublimates. The sublimated liquid K is transported away out of the cavity 102 as sublimate S.

For example, the at least one change of direction of the gas is performed if the relative humidity in the process exhaust air P stagnates or reaches a specified value, such as a value of for example 5 to 30%. Two to three changes of direction of the gas may be performed.

With the at least one change of direction of the gas, a number of pressure surges D may be performed with the gas G. Approximately 5 to 10 pressure surges D are thereby performed, each with a duration of a few milliseconds.

In a step S4, the negative pressure in the cavity 102 is detected, wherein steps S1, S2 and S3 are performed until in step S3 a specified negative-pressure threshold value of the negative pressure is reached within a specified time period. This procedure is indicated in FIG. 9 via an arrow pointing from step S3 to step S1.

The specified negative-pressure threshold value can lie below 23 mbar, such as between 1 mbar and 20 mbar. The specified time period can be less than 5 minutes. The specified humidity value can be less than 5% relative humidity. If the limit of 23 mbars (water-vapour pressure at room temperature) is quickly reached, this is an indication that the drying was successful. If, on the other hand, the pressure stagnates just above 23 mbar, this is an indication of continuing sublimation.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Component
102 Cavity
104 Connection
106 Connection
108 Wall
110 Leak
200 Drying device
202 Line
204 Line
206 Branch
208 Line portion
210 Line portion
212 Branch
214 Line portion
216 Line portion
218 Gas supply
220 Line
222 Drying unit
224 Line
226 Branch
228 Line
230 Line
232 Line
234 Temperature sensor
236 Moisture sensor
238 Line
240 Vacuum pump
242 Pressure sensor
D Pressure surge
E Ice
G Gas
K Liquid
M1 Mirror
M2 Mirror
M3 Mirror
M4 Mirror
M5 Mirror
M6 Mirror
P Process exhaust air
S Sublimate
SR1 Direction of flow
SR2 Direction of flow
S1 Step
S2 Step
S3 Step
SA Step
V1 Valve
V2 Valve
V3 Valve
V4 Valve
V5 Valve
V6 Valve
V10 Valve device
x x-direction
y y-direction
z z-direction

What is claimed is:

1. A method of drying a cavity in a component of a projection exposure apparatus, the method comprising:
a) charging the cavity with a gas so that a liquid present in the cavity at least partially evaporates, and so that the gas together with the evaporated liquid are transported out of the cavity as process exhaust air;
b) detecting a relative humidity of the process exhaust air; and
c) applying a negative pressure to the cavity as soon as the relative humidity of the process exhaust air falls below a specified humidity value during b) so that liquid remaining in the cavity freezes and sublimates, and so that the sublimated liquid is transported out of the cavity as sublimate,
wherein a) comprises:
i) reversing a direction of flow of the gas through the cavity at least one time depending on the detected relative humidity of the process exhaust air; and/or
ii) ii) performing at least one pressure surge with the gas depending on the detected relative humidity of the process exhaust air.

2. The method of claim 1, comprising performing i) and/or ii) whenever the detected relative humidity of the process exhaust air stagnates or reaches a specified value.

3. The method of claim 1, comprising performing i) so that the direction of the flow of the gas through the cavity at least two times.

4. The method of claim 1, comprising performing i) and/or ii) whenever the relative humidity in the process exhaust air stagnates or reaches five to thirty percent.

5. The method of claim 1, comprising performing i), and performing a plurality of pressure surges with the gas during i).

6. The method of claim 1, comprising performing i), and performing five to ten pressure surges with the gas during i), wherein each pressure surge has a duration of a few milliseconds.

7. The method of claim 1, wherein b) comprises determining a difference between a humidity of the gas and a humidity of the process exhaust air.

8. The method of claim 1, further comprising detecting the negative pressure in the cavity, wherein a), b) and c) are performed until, during c), a specified negative-pressure threshold value of the negative pressure is reached within a specified time period.

9. The method of claim 8, wherein the specified negative-pressure threshold value is below twenty three millibars.

10. The method of claim 8, wherein the specified negative-pressure threshold value is between one millibar and twenty millibars.

11. The method of claim 8, wherein the specified time period is less than five minutes.

12. The method of claim 1, wherein the specified humidity value is less than five percent.

13. The method of claim 1, wherein the method comprises performing i).

14. The method of claim 1, wherein the method comprises performing i) and ii).

15. The method of claim 1, wherein the method comprises performing ii).

16. A drying device, comprising:
a gas supply configured to supply the drying device with a gas;
a valve device configured to charge the cavity with the gas so that a liquid in the cavity at least partially evaporates when the cavity charged with the gas, and so that the gas together with the evaporated liquid are transported out of the cavity as process exhaust air;
a moisture sensor configured to detect the relative humidity of the process exhaust air; and
a vacuum pump configured to apply a negative pressure to the cavity as soon as the relative humidity of the process exhaust air falls below a specified humidity value so that liquid remaining in the cavity freezes and sublimates, and so that the sublimated liquid is transportable out of the cavity as sublimate via the valve device,
wherein the drying device is configured to reverse a direction of flow of the gas through the cavity at least once depending on the detected relative humidity of the process exhaust air.

17. The drying device of claim 16, wherein the valve device fluidically connects the gas supply to a first connection of the cavity.

18. The drying device of claim 17, wherein the valve device fluidically connects the vacuum pump to a second connection of the cavity, the second connection of the cavity being different from the first connection of the cavity.

19. The drying device of claim 18, wherein the valve device comprises a first plurality of valves assigned to the first connection of the cavity and a second plurality of valves assigned to the second connection of the cavity, the first plurality of valves being different from the second plurality of valves.

20. The drying device of claim 16, further comprising a pressure sensor upstream of the vacuum pump, wherein the pressure sensor is configured to detect the negative pressure in the cavity.
